(19) United States
(12) Patent Application Publication
(10) Pub. No.: US 2007/0127604 A1
(43) Pub. Date: Jun. 7, 2007

(54) Receiver and infrared wireless-earphone

(75) Inventors: Takahiro Inoue, Katsuragi-shi (JP); Yasuyuki Matsuya, Atsugi-shi (JP); Takako Ishihara, Atsugi-shi (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA NIPPON TELEGRAPH & TELEPHONE CORP.

(21) Appl. No.: 11/603,137

(22) Filed: Nov. 22, 2006

(30) Foreign Application Priority Data
Dec. 6, 2005 (JP) 2005-352489

(51) Int. Cl. H03D 1/00

(52) U.S. Cl. 375/341

(57) ABSTRACT

A receiving section of an infrared receiver includes an error detecting section that detects, through an integrating circuit, a direct-current component of a 1-bit data sequence that is supplied in a form of a PDM signal. The direct-current component thus detected is compared with a reference voltage by the comparing circuit to determine whether the direct-current component is greater or smaller than the reference voltage, and a signal is outputted on the basis of a result of the comparison. When the direct-current component is decreased, it is determined that a bit error rate is greater. At this time, an output of sound from the infrared receiver is caused to become OFF.

This Nonprovisional application claims priority under 35 U.S.C. § 119(a) on Patent Application No. 352489/2005 filed in Japan on Dec. 6, 2005, the entire contents of which are hereby incorporated by reference.

### FIELD OF THE INVENTION

The present invention relates to a receiver, and particularly, relates to a device that performs wireless communications of audio data.

### BACKGROUND OF THE INVENTION

In recent years, devices that perform processing of digital audio signals have actively been developed. This is accompanied by vigorous development in techniques of processing digital audio signals for connecting devices. Generally, digital audio data adopts a PCM (Pulse Code Modulation) format. In this case, PCM signals of CD/MD/DVD and the like need to be converted into PDM signals by using a specific IC. For example, Patent Document 1 proposes a method in which, when communication of audio data is performed by using an infrared communication device of IrDA (Infrared Data Association) standard, a 1-bit data sequence modulated by PDM (Pulse Density Modulation) is transferred.

FIG. 15 shows a block diagram of a conventional infrared receiver. The figure shows an infrared receiver 101, which is an exemplary infrared wireless-earphone. The infrared receiver 101 includes a receiving section 102, a speaker driving section 103, and a speaker 104. When receiving, via the receiving section 102, a 1-bit data sequence of a PDM signal transmitted from a transmitter (not illustrated) via baseband transmission, the infrared receiver 101 reproduces an analog audio signal by causing the 1-bit data sequence to pass through a low pass filter provided to the speaker driving section 103, thereby causing the speaker 104 to drive.

As described above, in infrared communication devices, audio data is converted, at a sending-end by use of PDM, into pulse density data of pulse sequence. By this way, a received signal is easily converted into sound at a receiving-end by providing the receiving-end with a receiving device, a speaker, and means for driving the speaker.

Exemplary infrared receiving means of the conventional infrared communication device includes an IrDA receiving device and an infrared remote-control receiving device. Table 1 shows a specification of the IrDA receiving device, and Table 2 shows a specification of the infrared remote-control receiving device. Table 1 shows pulse widths and periods T with respect to respective transmission rates. The transmission rate includes high-speed specification FIR (4 Mbps), middle-speed specification MIR (1.152 Mbps), and low-speed specification SIR (2.4 kbps to 115.2 kbps). Further, as shown in Table 2, the pulse widths and the periods T differ depending on a transmission code in the case of the infrared remote-control receiving device.

In view of the transmission rate, high-speed specification FIR or medium-speed specification MIR of the IrDA receiving device is preferable for audio-data communications.

TABLE 1

| TRANSMISSION | | |
|---|---|---|
| RATE | PULSE WIDTH | PERIOD T |
| 4 Mbps (FIR) | (¼) · T | 500 nsec |
| 1.152 Mbps (MIR) | (¼) · T | 868 nsec |
| 2.4 kbps TO | ( 3/16) · T | 8.68 μsec TO |
| 115.2 kbps (SIR) | | 104 μsec |

TABLE 2

| TRANSMISSION | | |
|---|---|---|
| RATE | PULSE WIDTH | PERIOD T |
| 1 kbps OR BELOW | DIFFER | DIFFER |
| | DEPENDING ON | DEPENDING ON |
| | TRANSMISSION | TRANSMISSION |
| | CODE | CODE |

In an infrared receiver including the IrDA receiving device or the infrared remote-control receiving device, a bit error rate generally increases as a reception distance becomes longer. This causes a communication error to be generated. At this time, if audio-data transmission is performed by using a 1-bit data sequence, which is a PDM signal, the communication error becomes a noise. This causes tone quality to be deteriorated.

FIG. 16 shows received waveforms. FIG. 16(a) shows a normal received waveform. FIGS. 16(b) and 16(c) show received waveforms in the case where the bit error rate is increased. Specifically, FIG. 16(b) shows a waveform in which a “lost-pulse” occurs. The “lost-pulse” means that a pulse is entirely lost. FIG. 16(c) shows a waveform in which a “split-pulse” occurs. The “split-pulse” means that a pulse is partially lost in a temporal axis. In the cases of FIGS. 16(b) and 16(c), pulse density data of pulse sequences is not received correctly, and an error becomes a noise. This causes the tone quality to be deteriorated.

As described above, in the conventional infrared receiver that receives a 1-bit data sequence in the form of a PDM signal, a noise is generated if the bit error rate increases. This causes the tone quality to be deteriorated. Thus, conventionally, there has been a problem that sound becomes unpleasant when such noise is generated.

[Patent Document 1]

Japanese Unexamined Patent Publication No. 2004-135321 (published on Apr. 30, 2004)

[Patent Document 2]

Japanese Unexamined Patent Publication No. 2005-130088 (published on May 19, 2005)

### SUMMARY OF THE INVENTION

The present invention has as an object to provide: a receiver that receives a 1-bit data sequence of a PDM signal, and allows unpleasantness to be eased when a noise is generated due to bit errors; and an infrared wireless-earphone including the receiver.

To achieve the above object, a receiver according to the present invention is adapted so that the receiver receives audio data via wireless, which audio data, constituted of a 1-bit data sequence which has been subjected to pulse density modulation, is transmitted via baseband transmission, and includes: detecting unit for detecting a bit error rate; and comparing unit for (I) comparing the bit error rate detected by the detecting unit with a predetermined reference rate, and (II) outputting, (a) when the bit error rate is smaller than the reference rate, a signal that causes an output of reproduction of the audio data thus received to become ON, and, (b) when the bit error rate is greater than the reference rate, a signal that causes the output to become OFF.

In the above invention, the detecting unit detects a bit error rate of a received signal, and the comparing unit compares a result of the detection with a predetermined rate. When a result of the comparison by the comparing unit indicates that the bit error rate is smaller than the predetermined rate, an output of reproduction of audio data thus supplied is caused to become ON. On the other hand, when the result of the comparison indicates that the bit error rate is greater than the predetermined rate, the output is caused to become OFF. Accordingly, when the bit error rate is great, sound in which a noise is generated due to bit errors is prevented from being outputted.

The foregoing makes it possible to realize a receiver that receives a 1-bit data sequence of a PDM signal and allows unpleasantness to be eased when a noise is generated due to a bit error rate. This is an advantage of the present invention.

Further, the receiver according to the present invention is adapted so that the detecting unit includes an integrator to detect a direct-current component of a received signal; and the comparing unit includes a comparator to compare the direct-current component detected by the detecting unit with a reference voltage that is determined in accordance with the reference rate.

In the above invention, the detecting unit causes the integrator to detect a direct-current component of a received signal. This allows the bit error rate to be detected on the basis of the magnitude of the direct-current component. Further, the comparing unit causes the comparator to compare the direct-current component thus detected with the reference voltage that is determined in accordance with the reference rate of the bit error rate. This makes it possible to determine whether the bit error rate is greater or smaller than the reference rate.

Accordingly, the detecting unit and the comparing unit are easily realized. This is an advantage of the present invention.

Further, the receiver according to the present invention is adapted so that the receiver further includes a monostable multivibrator circuit to generate and output a new pulse in response to each received pulse that constitutes the 1-bit data sequence of the audio data thus received, the detecting unit (I) being supplied with the new pulse that is outputted by the monostable multivibrator circuit and (II) including an integrator to detect a direct-current component of the new pulse, and the comparing unit including a comparator to compare the direct-current component detected by the integrator with a reference voltage that is determined in accordance with the reference rate.

In the above invention, the monostable multivibrator circuit generates a new pulse in response to a pulse of a received signal. This allows a pulse having a desired pulse width to be generated in response to a received signal, in such a manner as to be independent from a reception distance.

The detecting unit causes the integrator to detect the direct-current component of a signal that is outputted from the monostable multivibrator circuit. This allows the bit error rate to be detected on the basis of a magnitude of the direct-current component. Further, the comparing unit causes the comparator to compare the direct-current component thus detected with the reference voltage that is determined in accordance with the reference rate of the bit error rate. This makes it possible to determine whether the bit error rate is greater or smaller than the reference rate.

Accordingly, the detecting unit and the comparing unit are easily realized, and the bit error rate is detected impartially because the direct-current component detected by the detecting unit does not fluctuate depending on the reception distance. This is an advantage of the present invention.

Further, the monostable multivibrator circuit regenerates a pulse. Thus, if the pulse outputted from the monostable multivibrator circuit is generated such that the pulse has the same width as the pulse transmitted from the transmitter, it becomes possible to use the pulse in reproduction of audio data by the receiver. In this case, reproduction is performed suitably. This is an advantage of the present invention.

Further, the receiver according to the present invention is adapted so that the receiver further includes bit-error correcting unit for carrying out, before the detecting unit detects the bit error rate, a bit error correction by eliminating a bit error caused by a split-pulse.

In the above invention, before the detecting unit detects the bit error rate, the bit-error correcting unit corrects the bit error by eliminating a bit error that is caused by a split-pulse. At this time, the bit error is the one caused by a lost-pulse. The lost-pulse causes the direct-current component to change.

Accordingly, among pulses supplied to the detecting unit, a pulse whose width has fluctuated due to a split-pulse is prevented from causing an error to occur while the detecting unit detects the direct-current component. This is an advantage of the present invention.

Further, the receiver according to the present invention is adapted so that the receiver further includes a monostable multivibrator circuit to generate and output a new pulse in response to each received pulse that constitutes the 1-bit data sequence of the audio data thus received, the bit-error correcting unit causing the monostable multivibrator circuit to correct the split-pulse so that the split-pulse becomes a normal pulse when the monostable multivibrator circuit generates the new pulse, the detecting unit (I) being supplied with the new pulse that is outputted by the monostable multivibrator circuit and (II) including an integrator to detect a direct-current component of the new pulse, and the comparing unit including a comparator to compare the direct-current component detected by the integrator with a reference voltage that is determined in accordance with the reference rate.

In the above invention, the monostable multivibrator circuit generates a new pulse in response to a pulse of the received signal. This allows a pulse with a desired pulse width to be generated in response to a received signal, in such a manner as to be independent from a reception distance. Further, the bit-error correcting unit causes the monostable multivibrator circuit to correct the split-pulse when the monostable multivibrator circuit generates a new pulse. As such, the split-pulse becomes a normal pulse. Accordingly, the monostable multivibrator circuit always outputs a normal pulse.

The detecting unit causes the integrator to detect the direct-current component of a signal that is outputted from the monostable multivibrator circuit. This allows the bit error rate to be detected on the basis of a magnitude of the direct-current component. Further, the comparing unit causes the comparator to compare the direct-current component thus detected with the reference voltage that is determined in accordance with the reference rate of the bit error rate. This makes it possible to determine whether the bit error rate is greater or smaller than the reference rate.

Accordingly, the detecting unit and the comparing unit are easily realized, and the bit error rate is detected especially impartially because (i) the direct-current component detected by the detecting unit does not fluctuate depending on the reception distance, and (ii) the direct-current component no longer fluctuates due to a split-pulse. This is an advantage of the present invention.

Further, the monostable multivibrator circuit regenerates a pulse and corrects the split-pulse. Thus, if the pulse outputted from the monostable multivibrator circuit is generated such that the pulse has the same width as the pulse transmitted from the transmitter, it becomes possible to use the pulse in reproduction of audio data by the receiver. In this case, reproduction is performed suitably. This is an advantage of the present invention.

Further, the receiver according to the present invention is adapted so that the integrator has a cut-off frequency that is equal to or below a voice band.

In the above invention, a frequency band that is not lower than the voice band is eliminated in the integrator. This facilitates detecting the direct-current component. This is an advantage of the present invention.

Further, the receiver according to the present invention is adapted so that the comparator has a hysteresis characteristic.

In the above invention, the comparator has the hysteresis characteristic. This prevents an output of the comparator from chattering. This is an advantage of the present invention.

Further, the receiver according to the present invention is adapted so that the receiver includes a temperature compensating circuit to perform a temperature compensation for a pulse width of the new pulse that is outputted by the monostable multivibrator circuit.

In the above invention, the temperature compensating circuit is provided so that, even if the temperature fluctuates, a pulse width of a pulse supplied from the monostable multivibrator circuit is maintained stable. Accordingly, the direct-current component is detected highly accurately even if the temperature fluctuates. This is an advantage of the present invention.

Further, the receiver according to the present invention is adapted so that the temperature compensating circuit has a pulse width-temperature characteristic that causes the pulse width to be constant at around 37° C.

Accordingly, in the case where the receiver is to be provided to an apparatus that is to be worn by a human body, the direct-current component is detected under actual-use conditions. This is an advantage of the present invention.

Further, the receiver according to the present invention is adapted so that the temperature compensating circuit includes a trimming circuit to adjust a pulse-width-temperature characteristic.

The above invention allows the trimming circuit to adjust the pulse-width-temperature characteristic when a value of a device of the temperature compensating circuit fluctuates due to a change in processing. Accordingly, even if there arises a change in processing, the direct-current component is detected highly accurately. This is an advantage of the present invention.

Further, an infrared wireless earphone according to the present invention is adapted so that the infrared wireless earphone includes the receiver, the baseband transmission being performed via infrared rays, the receiver outputting sound through an earphone.

This allows unpleasantness to be eased when a bit error causes a noise in a signal supplied to the infrared wireless-earphone. This is an advantage of the present invention.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a block diagram schematically illustrating a substantial part of an infrared receiver, according to an embodiment of the present invention.

FIG. 2 is a circuit diagram illustrating a configuration of an error detecting section that is provided to the infrared receiver shown in FIG. 1.

FIG. 3 is a timing chart explaining exemplary operation 1 in response to a reception status of the infrared receiver shown in FIG. 1.

FIG. 4 is a timing chart explaining exemplary operation 2 in response to a reception status of the infrared receiver shown in FIG. 1.

FIG. 5 is a circuit diagram illustrating a configuration of a hysteresis comparator.

FIGS. 6(a) and 6(b) are circuit diagrams each explaining an operation of the hysteresis comparator shown in FIG. 5.

FIGS. 7(a) and 7(b) are timing charts each explaining an advantage that is produced by providing the infrared receiver of FIG. 1 with the hysteresis comparator of FIG. 5.

FIG. 8 is a circuit diagram illustrating another configuration of the error detecting section that is provided to the infrared receiver of FIG. 1, according to an embodiment of the present invention.

FIG. 9 is a timing chart explaining an operation of the error detecting section shown in FIG. 8.

FIG. 10 is a circuit diagram illustrating another configuration of the error detecting section that is provided to the infrared receiver of FIG. 1, according to an embodiment of the present invention.

FIG. 11 is a timing chart explaining an operation of the error detecting section shown in FIG. 10.

FIG. 12 is a circuit diagram illustrating a configuration that causes a PTAT current to be generated.

FIG. 13 is a graph showing a pulse-width-temperature characteristic in the case where a temperature compensating circuit is employed.

FIG. 14 is a circuit diagram illustrating a configuration of a trimming circuit.

FIG. 15 is a block diagram illustrating a substantial part of an infrared receiver, according to a conventional technique.

FIGS. 16(a) to (c) are waveform charts each showing a waveform of a received signal.

### DESCRIPTION OF THE EMBODIMENTS

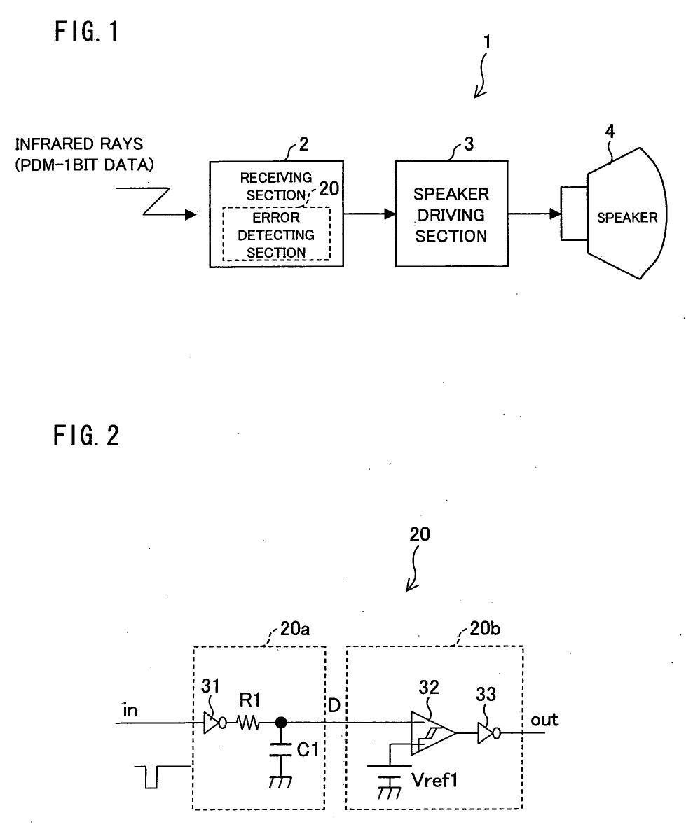

The following explains embodiments of the present invention, with reference to FIGS. 1 to 14.

### Embodiment 1

The following explains an embodiment of the present invention, with reference to FIGS. 1 to 7.

FIG. 1 shows a structure of an infrared receiver (receiver) 1 according to the present embodiment. The infrared receiver 1 is provided to an infrared wireless-earphone and the like, and includes a receiving section 2, a speaker driving section 3, and a speaker 4. The receiver outputs sound via an earphone. Further, the receiving section 2 includes an error detecting section 20.

Audio data is transmitted, as a transmitted signal, from a transmitter (not illustrated) via baseband transmission, which audio data is constituted of a 1-bit data sequence of a PDM signal. In the present embodiment, it is assumed that a period (T) of the transmitted signal is 500 nsec to 868 nsec (1.152 MHz to 2 MHz). The audio data is receivable by an IrDA receiving device of medium-speed specification MIR (1.152 Mbps) or high-speed specification FIR (4 Mbps).

The receiving section 2 amplifies an infrared signal supplied from the transmitter. The signal thus amplified is passed through a low pass filter of the speaker driving section 3 so that an analogue signal is reproduced. The analogue signal thus reproduced causes the speaker 4 to be driven. At this time, the receiving section 2 causes the error detecting section 20 to detect the bit error rate of the received signal.

FIG. 2 shows a configuration of the error detecting section 20. The error detecting section 20 includes an integrating circuit (detecting means) 20a and a comparing circuit (comparing means) 20b.

The integrating circuit 20a includes an inverter 31, a resistor R1, and a capacitor C1. An input signal in (hereinafter, a waveform of the input signal in will be expressed in voltage) of the integrating circuit 20a is the audio data of a 1-bit data sequence that is supplied to the infrared receiver 1. The inverter 31 inverts the input signal in between High and Low. One end of the resistor R1 is connected to an output-end of the inverter 31, and the other end of the resistor R1 is connected to one end of the capacitor C1. Another end of the capacitor C1 is connected to a GND. A low-frequency component, especially a direct-current component, of an output voltage of the inverter 31 is outputted as a voltage of the capacitor C1, as a consequence of integral action of the resistor R1 and the capacitor C1. The voltage of the capacitor C1 becomes an output voltage D of the integrating circuit 20a. Note that the resistor R1 and the capacitor C1 constitute an integrator. Accordingly, the integrating circuit is realized by the resistor R1 and the capacitor C1. However, since the inverter 31 merely inverts a logic and functions as buffer, the inverter 31, the resistor R1, and the capacitor C1 are collectively referred to as the integrating circuit 20a in the present embodiment.

The comparing circuit 20b includes a comparator 32 and an inverter 33. The comparator 32 compares the output voltage D of the integrating circuit 20a with a reference voltage Vref1 to determine whether the output voltage D is greater or smaller than the reference voltage Vref1. Then, the comparator 32 outputs a High signal or a Low signal in accordance with a result of the comparison. The inverter 33 inverts the output of the comparator 32 between High and Low to produce an output voltage out of the comparing circuit 20b (hereinafter, a waveform of the output voltage out will be expressed in voltage).

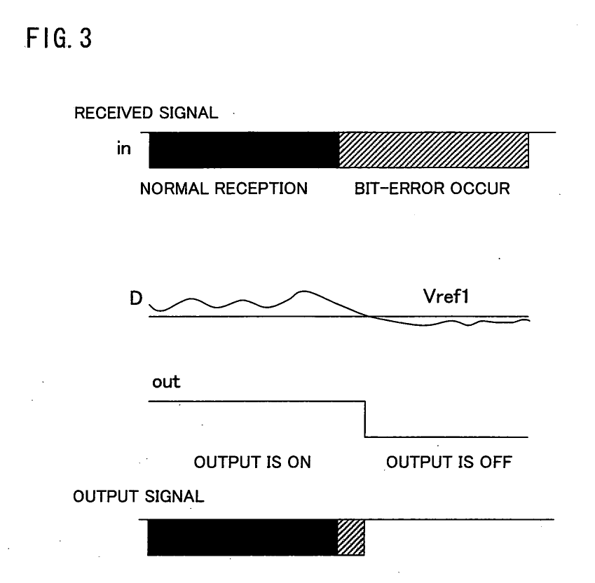

FIG. 3 shows respective waveforms of the input signal in, the output voltage D, and the output voltage out, of the error detecting section 20.

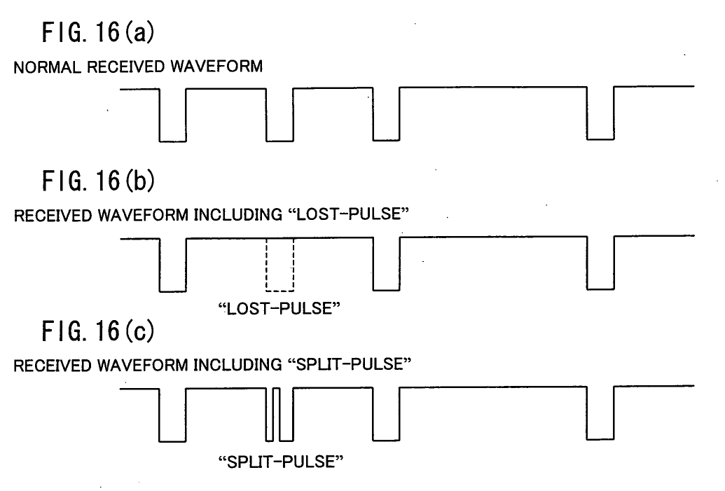

During a period in which the input signal in is supplied normally, a normal received-waveform as shown in FIG. 16(a) is inverted between High and Low. The normal received-waveform thus inverted is increased due to integral action of the resistor R1 and the capacitor C1 so as to be greater than the reference voltage Vref1. The integrating circuit 20a outputs the signal as the output voltage D. The output voltage D represents a low-frequency component of a received signal, which low-frequency component includes a direct-current component. Therefore, the output voltage D fluctuates depending on a pulse density of the PDM signal at respective moments. In the comparing circuit 20b, the comparator 32 compares the output voltage D with the reference voltage Vref1. The comparator 32 determines that the output voltage D is greater than the reference voltage Vref1, so that a Low signal is outputted. Thus, the output voltage out is High.

On the other hand, during a period in which a bit error occurs in the input signal in, a signal with the waveform shown in FIG. 16(b) and including a “lost-pulse” and a “split-pulse” is inverted between High and Low. Then, the signal thus inverted becomes the output voltage D as a consequence of integral action of the resistor R1 and the capacitor C1. In this case, a pulse is entirely or partially lost. This causes the direct-current component to decrease, and therefore an output voltage D is usually smaller than that in the case where the signal is received normally. Accordingly, as the bit error rate increases, the output voltage D decreases gradually. For this reason, there exists a bit error rate at which the output voltage D is smaller than the reference voltage Vref1. In the present embodiment, a threshold rate of an allowable rate of the bit error rate is set at a bit error rate at which an output voltage D equivalent to the reference voltage Vref1 is generated. In the comparing circuit 20b, the comparator 32 compares the output voltage D with the reference voltage Vref1. If the comparator 32 determines that the output voltage D is smaller than the reference voltage Vref1, then a High signal is outputted. Thus, the output voltage out is Low.

FIG. 3 shows a case in which a normal reception period is followed by a bit-error occurrence period in which a bit-error occurs. The output voltage D is greater than the reference voltage Vref1 during the normal reception period, but gradually decreases after a transition from the normal reception period to the bit-error occurrence period. Eventually, the output voltage D becomes smaller than the reference voltage Vref1.

In the present embodiment, the reference voltage Vref1 is set in accordance with a reference rate of the bit error rate. During the normal reception period, an output of reproduction of audio data supplied from the infrared receiver 1 is caused to be ON by a High output voltage out. On the other hand, during the period in which the bit error rate is greater than the reference rate, the output is caused to be OFF by a Low output voltage out. If the comparator 32 determines that the output voltage D is greater than the reference voltage Vref1, it means that the bit error rate is smaller than the reference rate. On the other hand, if the output voltage D is determined as smaller than the reference voltage Vref1, it means that the bit error rate is greater than the reference rate.

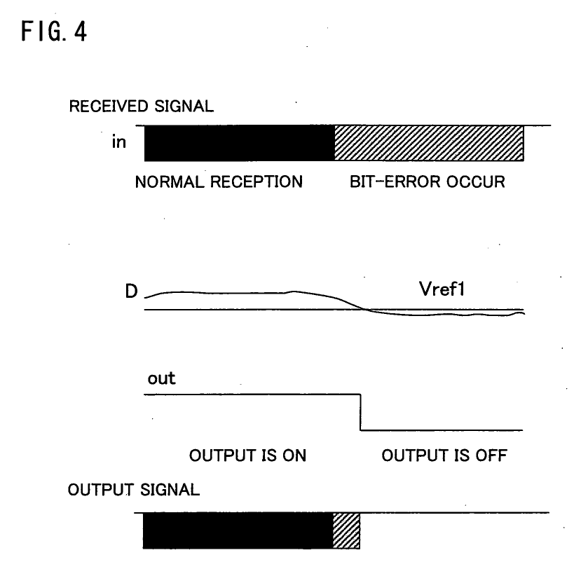

The 1-bit data sequence of the PDM signal has frequency components of a voice band (approximately 300 Hz to 20 kHz). Therefore, as described above, the waveform of the output voltage D of the integrating circuit 20a fluctuates depending on the frequency components. If the cut-off frequency fc of the integrating circuit 20a is set at 300 Hz or below to eliminate signal components of 300 Hz to 20 kHz, it becomes easy to detect the direct-current component because a low-frequency component other than the direct-current component is small. FIG. 4 shows a waveform of the output voltage D in the case where the cut-off frequency of the integrating circuit 20a is equal to or below the voice band. In this case, the proportion of the direct-current component increases, and the output voltage D fluctuates less. This facilitates detecting the direct-current component.

The following specifically explains the comparator 32. As indicated by a symbol as shown in FIG. 2, the comparator 32 may be realized by a hysteresis comparator. Because the transmitted signal is the PDM signal, components of the signal fluctuate within a range, depending on the pulse density. Accordingly, the output voltage D of the integrating circuit 20a also fluctuates within a range. At this time, if the output voltage D fluctuates at around the reference voltage Vref1, the output voltage D changes between a greater value and a smaller value than the reference voltage Vref1. This may generate a malfunction that the output of the comparator 32 frequently changes between ON and OFF due to chattering. If, however, the comparator 32 is given a hysteresis characteristic, it becomes possible to reduce the malfunction. In the case where the comparator 32 is given a hysteresis characteristic, if the output voltage out changes from High to Low, then the reference voltage Vref1 is increased. On the other hand, if the output voltage out changes from Low to High, then the reference voltage Vref1 is decreased. By this way, a malfunction due to fluctuation in the output voltage D is prevented.

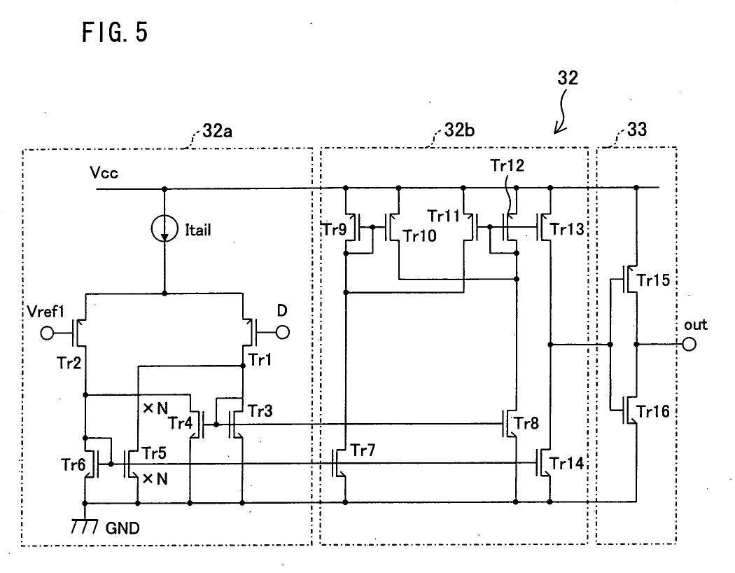

FIG. 5 shows a circuit diagram of the comparator 32, which is realized by a hysteresis comparator.

The comparator 32 includes a comparing section 32a and a level-shifting section 32b. Further, the inverter 33 is connected to an output-end of the level-shifting section 32b.

The comparing section 32a includes: a constant-current source Itail; transistors Tr1 and Tr2, each of which is realized by a P-channel type MOS transistor; and transistors Tr3 to Tr6, each of which is realized by an N-channel type MOS transistor. The level-shifting section 32b includes: transistors Tr9 to Tr13, each of which is realized by a P-channel type MOS transistor; and transistors Tr7, Tr8, and Tr14, each of which is realized by an N-channel type MOS transistor.

The inverter 33 is realized by a CMOS inverter, and includes: a transistor Tr15, which is realized by a P-channel type MOS transistor; and a transistor Tr16, which is realized by an N-channel type MOS transistor.

The following explains how devices are connected in the comparing section 32a.

A source of the transistor Tr1 and a source of the transistor Tr2 are connected to each other. The constant-current source Itail is provided across a power source Vcc and a connecting point of the transistors Tr1 and Tr2. A gate of the transistor Tr1 is an input terminal of the output voltage D of the integrating circuit 20a, and a gate of the transistor Tr2 is an input terminal of the reference voltage Vref1. The constant-current source Itail causes a constant current Itail to pass from the power source Vcc to the transistors Tr1 and Tr2.

The transistors Tr5 and Tr6 constitute a current mirror circuit. The transistor Tr5 causes a drain current to pass, which drain current is N times greater than that in the transistor Tr6. A drain of the transistor Tr6 is connected to a drain of the transistor Tr2. A source of the transistor Tr6 is connected to a GND. A drain of the transistor Tr5 is connected to a drain of the transistor Tr1. A source of the transistor Tr5 is connected to the GND. A gate of the transistor Tr5 and a gate of the transistor Tr6 are connected to each other. A connecting point of the gates of the transistors Tr5 and Tr6 is connected to a drain of the transistor Tr6.

The transistor Tr3 and the transistor Tr4 constitute a current mirror circuit. The transistor Tr4 causes a drain current to pass, which drain current is N times greater than that in the transistor Tr3. A drain of the transistor Tr3 is connected to a drain of the transistor Tr1. A source of the transistor Tr3 is connected to the GND. A drain of the transistor Tr4 is connected to a drain of the transistor Tr2. A source of the transistor Tr4 is connected to the GND. A gate of the transistor Tr3 and a gate of the transistor Tr4 are connected to each other. A connecting point of the gates of the transistors Tr3 and Tr4 is connected to a drain of the transistor Tr3.

The following explains how devices are connected in the level-shifting section 32b.

A gate of the transistor Tr7 is connected to the gates of the transistors Tr5 and Tr6. A source of the transistor Tr7 is connected to the GND. A gate of the transistor Tr8 is connected to the gates of the transistors Tr3 and Tr4. A source of the transistor Tr8 is connected to the GND.

The transistor Tr9 and the transistor Tr10 constitute a current mirror circuit. An electric-current ratio of the transistors Tr9 and Tr10 is 1:1. A drain of the transistor Tr9 is connected to a drain of the transistor Tr7. A source of the transistor Tr9 is connected to the power source Vcc. A drain of the transistor Tr10 is connected to a drain of the transistor Tr8. A source of the transistor Tr10 is connected to the power source Vcc. A gate of the transistor Tr9 and a gate of the transistor Tr10 are connected to each other. A connecting point of the gates of the transistors Tr9 and Tr10 is connected to a drain of the transistor Tr9.

The transistor Tr11 and the transistor Tr12 constitute a current mirror circuit. An electric-current ratio of the transistors Tr11 and Tr12 is 1:1. A drain of the transistor Tr12 is connected to a drain of the transistor Tr8. A source of the transistor Tr12 is connected to the power source Vcc. A drain of the transistor Tr11 is connected to a drain of the transistor Tr7. A source of the transistor Tr11 is connected to the power source Vcc. A gate of the transistor Tr11 and a gate of the transistor Tr12 are connected to each other. A connecting point of the gates of the transistors Tr11 and Tr12 is connected to a drain of the transistor Tr12.

A gate of the transistor Tr13 is connected to the gates of the transistors Tr11 and Tr12. A source of the transistor Tr13 is connected to the power source Vcc. A gate of the transistor Tr14 is connected to the gates of the transistors Tr5, Tr6, and Tr7. A source of the transistor Tr14 is connected to the GND. A drain of the transistor Tr13 and a drain of the transistor Tr14 are connected to each other. A connecting point of the drains of the transistors Tr13 and Tr14 is an output terminal of the level-shifting section 32b.

The following explains how devices are connected in the inverter 33.

A gate of the transistor Tr15 and a gate of the transistor Tr16 are connected to the output terminal of the level-shifting section 32b. A source of the transistor Tr15 is connected to the power source Vcc. A source of the transistor Tr16 is connected to the GND. A drain of the transistor Tr15 and a drain of the transistor Tr16 are connected to each other. A connecting point of the drains of the transistors Tr15 and Tr16 is an output terminal of the inverter 33. In other words, the connecting point is an output terminal of the comparing circuit 32.

The following explains operations of the comparing circuit 32, which is configured as described above.

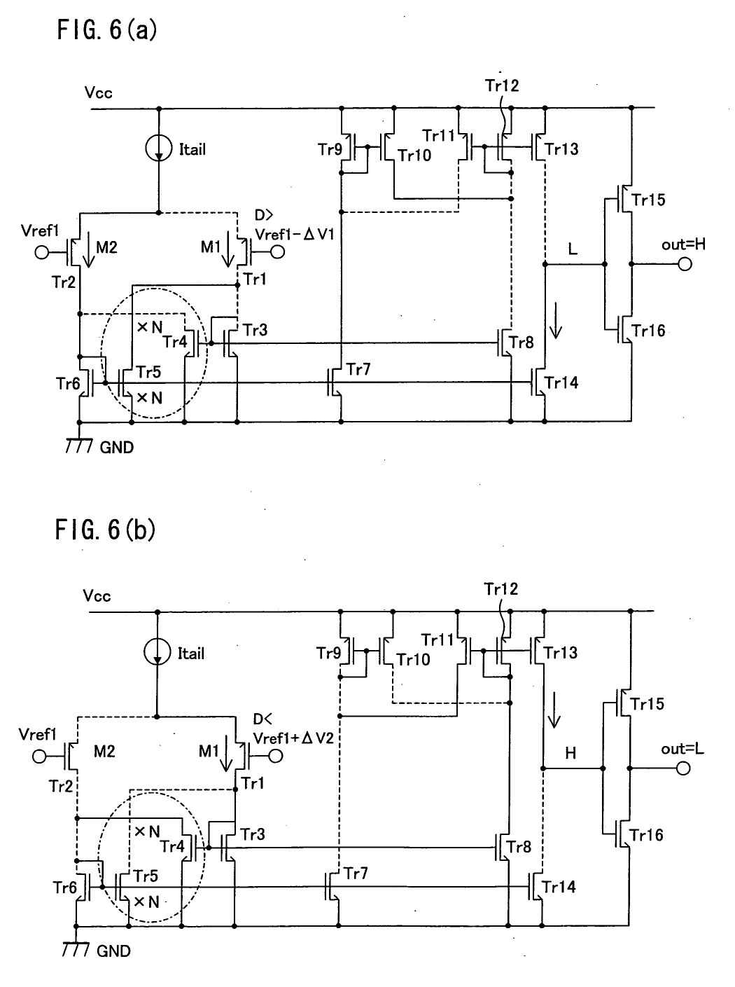

FIG. 6(a) shows operations in the case where the output voltage D of the integrating circuit 20a changes from a greater value to a smaller value. FIG. 6(b) shows operations performed in the case where the output voltage D changes from a smaller value to a greater value.

FIG. 6(a) shows a case in which the output voltage D is great, and the output voltage out of the comparing circuit 32 is High.

When D>Vref1−ΔV1, no electric current passes through the transistor Tr1. If the transistor Tr2 is overdriven, no drain current passes through the transistor Tr3, and thus no drain current passes through the transistor Tr4. Accordingly, the transistor Tr6 becomes ON. Thus, the transistor Tr5 also becomes ON. However, no drain current passes through the transistor Tr5. As a result, a drain-source voltage Vds of the transistor Tr5 becomes 0V, gate potentials of the transistors Tr3 and Tr4 become GND, and the transistors Tr3 and Tr4 become OFF.

At this time, the transistors Tr7 and Tr14 become ON, whereas the transistor Tr8 becomes OFF. Further, even though the transistors Tr9 and Tr10 become ON, no drain current passes through the transistor Tr10. Therefore, a drain-source voltage Vds of the transistor Tr10 becomes 0V. Consequently, a gate potential of the transistors Tr11 and Tr12 becomes high, and therefore the transistors Tr11 and Tr12 become OFF. The transistor Tr13 also become OFF. The broken line in FIG. 6(a) indicates a portion where no electric current passes when the transistors are OFF. Consequently, the transistor Tr15 becomes ON, and the transistor Tr16 becomes OFF. Thus, the output voltage out is High.

If (I) the output voltage D decreases and becomes D=Vref1−ΔV1, (II) the transistor Tr2 is released at this time to be no longer overdriven, so that the drain current of the transistor Tr2 is allowed to decrease, and (III) a drain current comes to pass through both of the transistor Tr1 and the transistor Tr2, then the drain current having passed through the transistor Tr1 passes through the transistor Tr5. Consequently, the drain current of the transistor Tr1 becomes N times greater than the drain current of the transistor Tr2. Accordingly, M1={N/(N+1)}×Itail, and M2={1/(N+1)}×Itail are satisfied, where M1 is the drain current of the transistor Tr1, and M2 is the drain current of the transistor Tr2. Thus, a differential pair is balanced.

At this time, the difference in gate-source voltage Vgs between the transistor Tr1 and the transistor Tr2 is ΔV. The transistor Tr1 and the transistor Tr2 are equal in source potential. Therefore, if it is assumed that the drain current M1 and the drain current M2 are equal in W/L ratio (W indicates a gate width, whereas L indicates a gate length), then the following formulae are satisfied, where Vgs1 is the gate-source voltage of the transistor Tr1, and Vgs2 is the gate-source voltage of the transistor Tr2:
Vref1+Vgs2=Vref1−ΔV1+Vgs1

Thus,

$$\begin{matrix}Δ V 1 = Vgs 1 - Vgs 2 \\ = {2}^{1 / 2} \times Vov \times \{ {( N / ( N + 1 ) )}^{1 / 2} - {( 1 / ( N + 1 ) )}^{1 / 2} \}\end{matrix} \qquad ( 1 )$$

Note that
Vov=(Itail/(μ0×Cox×W/L))^{1/2}

where μ0 indicates mobility of carrier, Cox indicates a capacitance of a gate insulating film, and Vov indicates an overdriving voltage of the transistors Tr1 and Tr2, which overdriving voltage is provided to pass the drain currents M1 and M2, in the case where no hysteresis is provided (N=1).

Further, when the output voltage D decreases further and becomes D<Vref1−ΔV1, the drain current of the transistor Tr1 increases. This causes a current of the transistor Tr5 to increase. However, when the drain current of the transistor Tr1 increases, the drain current of the transistor Tr2 decreases. This does not allow the current of the transistor Tr5 to increase. Accordingly, the drain current of the transistor Tr1 rapidly charges the gate of the transistor Tr3 so that the transistor Tr3 becomes ON. Consequently, the drain-source voltage Vds of the transistor Tr5 becomes high. This causes the transistor Tr4 to become ON.

However, the transistor Tr4 passes a current that is N times greater than the current of the transistor Tr3. This causes the transistor Tr4 to increase the current of the transistor Tr2. However, the current of the transistor Tr2 decreases. Therefore, the transistor Tr4 absorbs a current from the gate of the transistor Tr6. Consequently, the gate potentials of the transistors Tr5 and Tr6 decrease, so that the transistors Tr5 and Tr6 become OFF. However, there is a limit for the current to be absorbed. When the limit is reached, the drain current no longer passes through the transistor Tr4. Consequently, the drain-source voltage Vds of the transistor Tr4 becomes 0V, and the gate potentials of the transistors Tr5 and Tr6 become GND. As a result, the drain current does not pass through the transistor Tr2 any more.

As the foregoing explains, the balance is unstable when D=Vref1−ΔV1, and an electric-current distribution of the circuit inverts as soon as D becomes D<Vref1−ΔV1. This causes the electric-current distribution to become inverted in the level-shifting section 32b. Thus, the output voltage out is Low.

FIG. 6(b) shows a circuit in the case where the output voltage D of the integrating circuit 20a increases after the output voltage out becomes Low as a consequence of the operations in FIG. 6(a). In the figure, the output voltage out is Low initially.

In FIG. 6(a), the source potentials of the transistors Tr1 and Tr2 are higher at the time after D becomes D<Vref1−ΔV1 than at a moment of transition from D=Vref1−ΔV1 to D<Vref1−ΔV1. The reason therefor is that the transition is carried out by positive feedback, and the transistor Tr1 becomes overdriven when D becomes, even slightly, D<Vref1−ΔV1. Accordingly, when the output voltage D increases in FIG. 6(b) after the output voltage out becomes Low, the output voltage D needs to increase until the output voltage D becomes equal to Vref1+ΔV2, which is greater than Vref1−ΔV1. Otherwise, the drain current of the transistor Tr1 decreases, and therefore the drain current is not caused to pass through the transistor Tr2. Accordingly, when D<Vref1+ΔV2, the drain current passes through the transistor Tr1, while no drain current passes through the transistor Tr2. At this time, the electric-current distribution is same as D<Vref1−ΔV1 in FIG. 6(a). Consequently, the output voltage out becomes Low.

When the output voltage D increases and becomes equal to Vref1+ΔV2, the drain current passes through both the transistor Tr1 and the transistor Tr2.

At this time, M1={1/(N+1)}×Itail, where M1 is the drain current of the transistor Tr1, and M2={N/(N+1)}×Itail. Thus, the differential pair is balanced. At this time:
Vref1+Vgs2=Vref1+ΔV2+Vgs1
Thus,

$$\begin{matrix}Δ V 2 = Vgs 2 - Vgs 1 \\ = {2}^{1 / 2} \times Vov \times \{ {( N / ( N + 1 ) )}^{1 / 2} - {( 1 / ( N + 1 ) )}^{1 / 2} \}\end{matrix} \qquad ( 2 )$$

Accordingly, the formula below is led from formulae (1) and (2) above:
ΔV1=ΔV2=ΔV
Vref1−ΔV1 and Vref1+V2 are symmetric about Vref1.

Thereafter, when the output voltage D increases further and eventually becomes D>Vref1+ΔV2, the electric-current distribution becomes equal to that in the case where D>Vref1−ΔV1 as shown in FIG. 6(a). Thus, the output voltage out becomes High. At this time, no drain current passes through the transistor Tr1 due to action of positive feedback, and the transistor Tr2 becomes overdriven. When the output voltage D decreases therefrom, the changes explained in FIG. 6(a) occur.

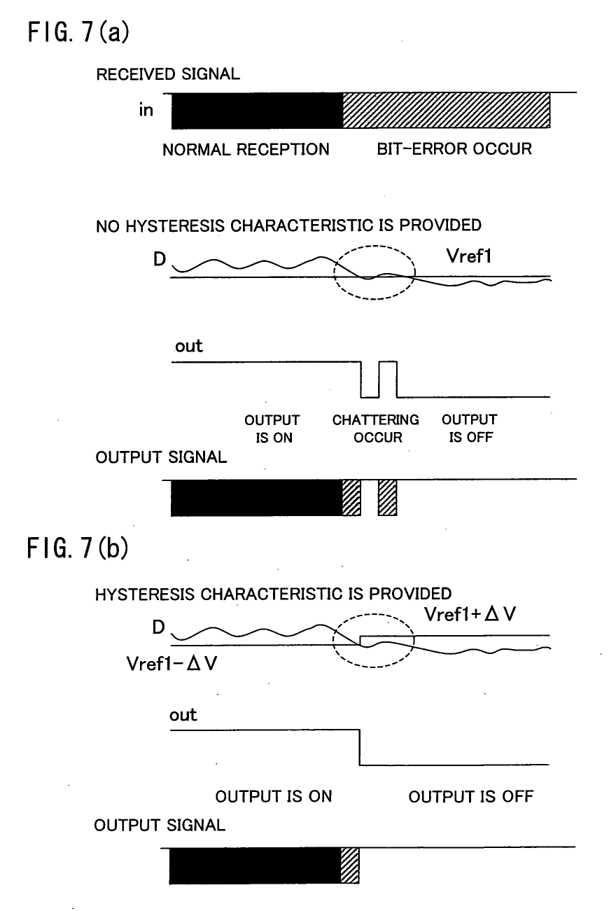

FIG. 7 shows differences in waveform between the case where a hysteresis characteristic is provided and the case where no hysteresis characteristic is provided. FIG. 7(a) shows a waveform in the case where no hysteresis characteristic is provided. If the output voltage D fluctuates at around the reference voltage Vref1 during the bit-error occurrence period, chattering occurs in the output voltage out. Accordingly, the output of reproduction of audio data from the infrared receiver 1 switches between ON and OFF frequently. FIG. 7(b) shows a waveform in the case where the hysteresis characteristic is provided. In this case, even if the output voltage D fluctuates at around the Vref1 during the bit-error occurrence period, the threshold value of the comparator 32 is changed to Vref1+ΔV once the output voltage D becomes smaller than Vref1−ΔV. Accordingly, the output voltage out is prevented from chattering, so that the output of reproduction of audio data from the infrared receiver 1 does not switch between ON and OFF frequently.

### Embodiment 2

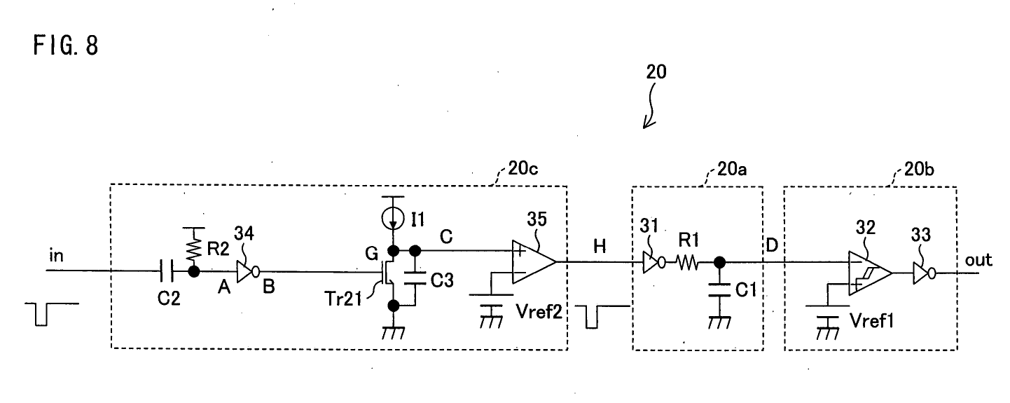

The following explains another embodiment of the present invention, with reference to FIGS. 8 to 14.

FIG. 8 shows a configuration of an error detecting section 20 that is provided to the infrared receiver 1 according to the present embodiment. The error detecting section 20 is realized by an error detecting section 20 shown in FIG. 2 and further including a monostable multivibrator circuit 20c.

The monostable multivibrator circuit 20c is supplied with an input signal in, which is a signal supplied to the infrared receiver 1, and outputs an output signal H. The output signal H is supplied to the integrating circuit 20a, and used as an audio signal to be reproduced by the infrared receiver 1. In the present embodiment, the infrared receiver 1 causes the integrating circuit 20a to accurately detect a bit error, regardless the distance from the transmitter. At this time, the integrating circuit 20a detects a “lost-pulse” but does not detect a “split-pulse”.

The monostable multivibrator circuit 20c includes a capacitor C2, a resistor R2, an inverter 34, a constant-current source I1, a transistor Tr21, a capacitor C3, and a comparator 35.

One end of the capacitor C2 is an input terminal for the input signal in, and the other end of the capacitor C2 is connected to one end of the resistor R2. Another end of the resistor R2 is pulled up by the power source. An input terminal of the inverter 34 is connected to a connecting point A of the capacitor C2 and the resistor R2. The transistor Tr21 is realized by an N-channel type MOS transistor. A gate of the transistor Tr21 is connected to an output terminal B of the inverter 34.

The constant-current source I1 is provided across the power source and a drain of the transistor Tr21, and causes a constant current I1 to pass to the transistor Tr21. A source of the transistor Tr21 is connected to the GND. The capacitor C3 is connected in parallel to the transistor Tr21. A non-inverting input terminal of the comparator 35 is connected to a connecting point C of a drain of the transistor Tr21 and the capacitor C3. An inverting input terminal of the comparator 35 is given a reference voltage Vref2. An output terminal of the comparator 35 is an output terminal H of the monostable multivibrator circuit 20c.

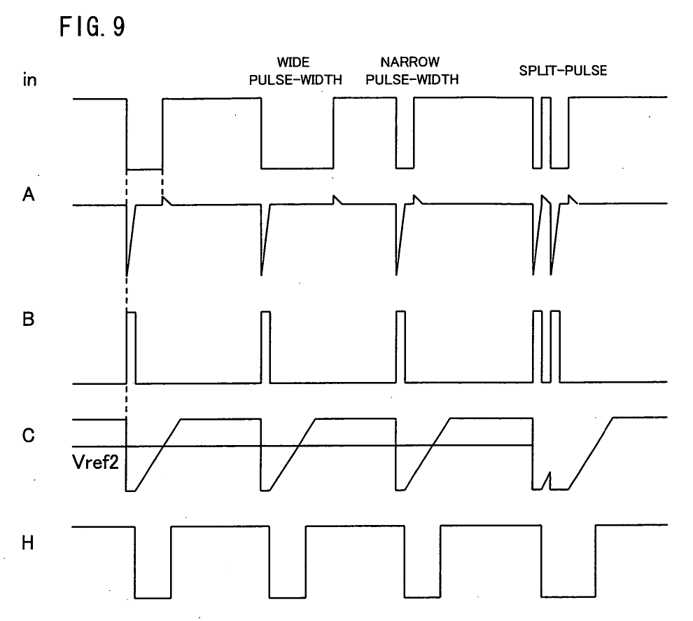

The following explains operations of the monostable multivibrator circuit 20c configured as explained above, with reference to FIG. 9.

If a pulse shown at leftmost in FIG. 9 is received, a start edge of the pulse causes a voltage of one input end of the capacitor C2 to immediately drop. This causes a charging current to pass from the power source to the capacitor C2 so that a voltage drop occurs in the resistor R2. The voltage drop gradually becomes small until charging of the capacitor C2 is finished. Consequently, triggers are generated as shown in the waveform at point A. The waveform is supplied to the inverter 34, and is outputted in the form of a thin rectangular-wave pulse as shown in the waveform at point B. The waveform is supplied to the gate of the transistor Tr21.

By that time, the capacitor C3 has already been charged by the constant-current source I1. However, as the transistor Tr21 becomes ON, both terminals of the capacitor C3 short, and therefore the capacitor C3 discharges. Thus, the voltage of the capacitor C3 becomes 0V. If a pulse at point B falls, then the transistor Tr21 becomes OFF. The voltage of the capacitor C3 is proportional to time, as the constant current I1 is supplied from the constant-current source I1. The charging stops when the voltage of the capacitor C3 becomes equal to the voltage of the power source. Accordingly, a pulse is outputted at point H, which pulse becomes Low level during a period between (a) a time when the transistor Tr21 becomes ON, and the voltage of the capacitor C3 becomes smaller than the reference voltage Vref2, and (b) a time when the transistor Tr21 becomes OFF, and the voltage of the capacitor C3 becomes greater than the reference voltage Vref2. A pulse width at point H is expressed by the formula below:
Tpw=C3×Vref2/I1 (3)

In the manner as described above, the monostable multivibrator circuit 20c outputs one new pulse in response to an input of one pulse, and then is reset automatically.

As the distance between the transmitter and the infrared receiver 1 changes, a width of a received pulse fluctuates. In other words, as a reception distance changes, a width of a received pulse fluctuates. FIG. 9 shows a case in which the pulse width of the input signal in becomes wider, and a case in which the pulse width becomes narrower. An end-timing of a pulse of the point H of the monostable multivibrator circuit 20c is determined in accordance with a design of the circuit, and does not depend on an end-timing of a pulse of the input signal in. For this reason, even if the pulse width of the input signal in fluctuates, a pulse with the same width is always outputted of the point H. Equalization of the pulse width Tpw, which is expressed by formula (3), to a normal pulse width of the received signal allows the pulse of the point H to be used in reproduction of audio data. Further, in the case where the received signal includes a “split-pulse”, there are a plurality of start-timings of pulse. Thus, before one pulse period of a pulse supplied from the monostable multivibrator circuit 20c ends, a next pulse is triggered. Consequently, a slightly wide pulse in which a plurality of pulses are connected is outputted from the point H. On the other hand, in the case where the received signal includes a “lost-pulse”, no trigger is supplied to the monostable multivibrator circuit 20c. Thus, the voltage of the point H remains High.

Accordingly, although there exists a slightly wide pulse due to the “split-pulse”, the “lost-pulse” is what causes a reduction in the direct-current component of the signal supplied to the integrating circuit 20a. This makes it possible to (i) detect the “lost-pulse” as a bit error and (ii) change, between ON and OFF, the output of reproduction of audio data from the infrared receiver 1, in accordance with an output of the integrating circuit 20a. The bit error is detected by using a pulse whose width does not depend on the reception distance. Thus, the output voltage D, which is compared with the reference voltage Vref1 by the comparator 32, of the integrating circuit 20a does not depend on the reception distance. This allows impartial detection of a bit error rate regardless of the reception distance. Thus, it becomes possible to evaluate a bit error rate highly reliably.

Further, the voltage of the point H is used in reproduction of audio data by the infrared receiver 1. Because the pulse whose width does not depend on the reception distance is used, it is possible to prevent the sound pressure from fluctuating depending on the reception distance.

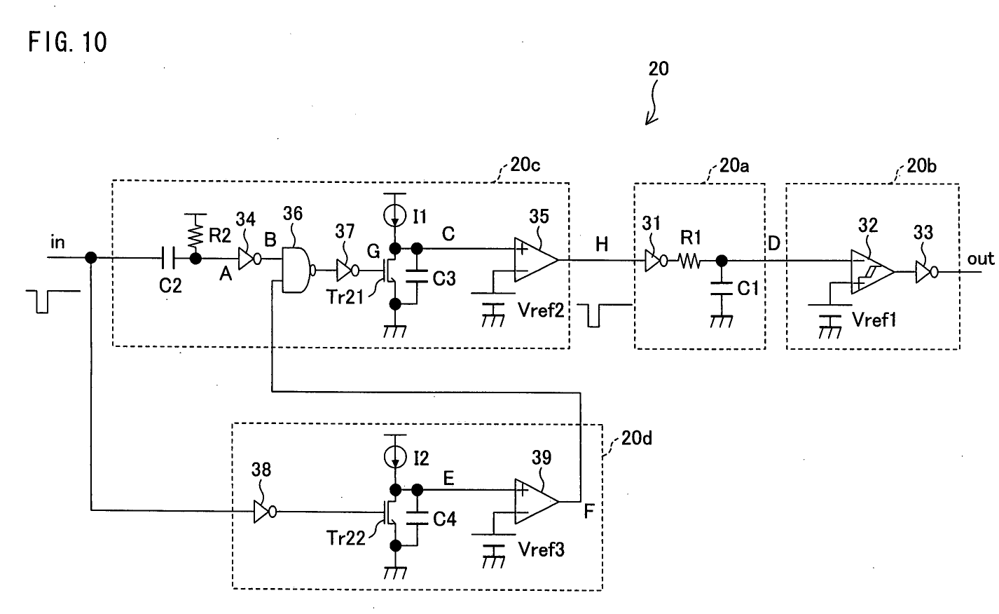

FIG. 10 shows a configuration of a modified embodiment of the present embodiment. The figure shows a configuration of the error detecting section 20. In the figure, a NAND circuit 36, an inverter 37, and a malfunction preventing circuit (bit-error correcting means) 20d are added to the monostable multivibrator circuit 20c of the error detecting section 20 shown in FIG. 8.

The NAND circuit 36 of the monostable multivibrator circuit 20c has two input terminals. One of the input terminals is connected to the output terminal of the inverter 34, and the other one of the input terminals is connected to the output terminal of the malfunction preventing circuit 20d. An input terminal of the inverter 37 is connected to an output terminal of the NAND circuit 36. An output terminal of the inverter 37 is connected to a gate G of the transistor Tr21.

The malfunction preventing circuit 20d includes an inverter 38, a constant-current source I2, a transistor Tr22, a capacitor C4, and a comparator 39. An input terminal of the inverter 38 is connected to an input terminal for the input signal in. The transistor Tr22 is realized by an N-channel type MOS transistor. A gate of the transistor Tr22 is connected to an output terminal of the inverter 38.

The constant-current source I2 is provided across the power source and a drain of the transistor Tr22, and causes a constant current I2 to pass to the transistor Tr22. A source of the transistor Tr22 is connected to the GND. The capacitor C4 is connected in parallel to the transistor Tr22. A non-inverting input terminal of the comparator 39 is connected to a connecting point E of a drain of the transistor Tr22 and the capacitor C4. A inverting input terminal of the comparator 39 is given a reference voltage Vref3. An output terminal of the comparator 39 is an output terminal F of the malfunction preventing circuit 20d, and is connected to an input terminal of the NAND circuit 36 described above.

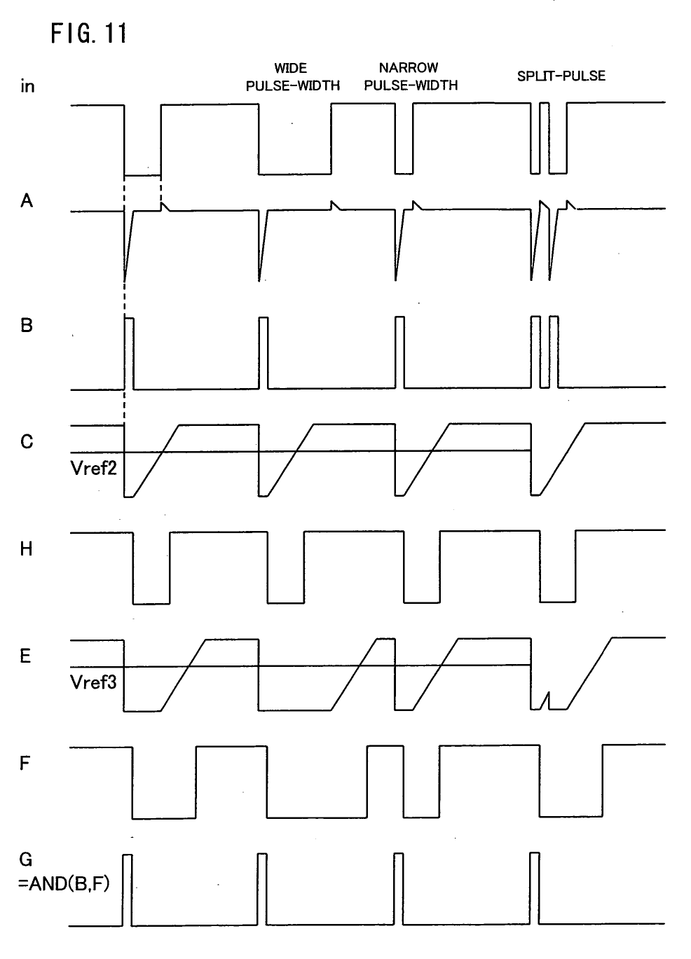

FIG. 11 shows waveforms of voltages at the respective points in the case where the malfunction preventing circuit 20d is employed. The waveform of the input signal in, the waveform at point A, and the waveform at point B in the figure are same as those shown in FIG. 9.

In the malfunction preventing circuit 20d, the capacitor C4 is supplied with a charging voltage from the constant-current source I2. The inverter 38 inverts a level of the input signal in, and the input signal in thus inverted is supplied to the gate of the transistor Tr22. During the period in which the signal is High, the transistor Tr22 becomes ON in response to the input signal in. Consequently, the capacitor C4 discharges, and the charging voltage becomes 0V. When a pulse of the input signal at the gate of the transistor Tr22 falls, the transistor Tr22 becomes OFF. Consequently, current from the constant-current source I2 starts charging the capacitor C4. The charging voltage increases until it reaches a voltage that is limited by a power-source voltage. When reaching the voltage limited by the power-source voltage, the charging voltage stops increasing. This is shown in FIG. 11 as a waveform of the point E.

The voltage of the point E is compared with the reference voltage Vref3 by the comparator 39. During a period in which the voltage of the point E is smaller than the reference voltage Vref3, the comparator 39 outputs a pulse, as an output voltage, that is Low. On the other hand, during a period in which the voltage of the point E is greater than the reference voltage Vref3, the comparator 39 outputs a pulse that is High. A waveform of the output voltage is shown in FIG. 11 as a waveform at the output terminal F.

The NAND circuit 36 performs a NAND operation with the use of a voltage at the output terminal F and a voltage of the point B of the monostable multivibrator circuit 20c. Then, a logic of an output of the NAND circuit 36 is inverted, resulting in a waveform of the point G as shown in FIG. 11. The waveform of the point G corresponds to start-timings of the respective pulses of the input signal in, which is supplied from the infrared receiver 1. For this reason, even if the input signal in includes the split-pulse, respective pulses of the point G only reflect initial pulse-falls of the respective pulses of the input signal in. Accordingly, after the pulse of the point G is supplied to the gate of the transistor Tr21, the waveform of the point C causes a same change in the charging voltage as (i) a pulse with a normal width, (ii) a pulse with a wide width, and (iii) a pulse with a narrow width, unlike in the case of FIG. 9 where the charging is carried out for a plurality of times. Accordingly, all of the received pulses, including a pulse that includes the split-pulse, are outputted at the point H as normal pulses having the same width.

This prevents the split-pulse from causing an error in detection of the direct-current component. Thus, it becomes possible to impartially detect a bit error rate. Further, in the case where the signal at the point H is used in reproduction of audio data, a received pulse that includes the split-pulse is corrected so that it becomes a normal pulse. Then, the normal pulse is used in reproduction. This enables especially suitable reproduction of audio data.

### Embodiment 3

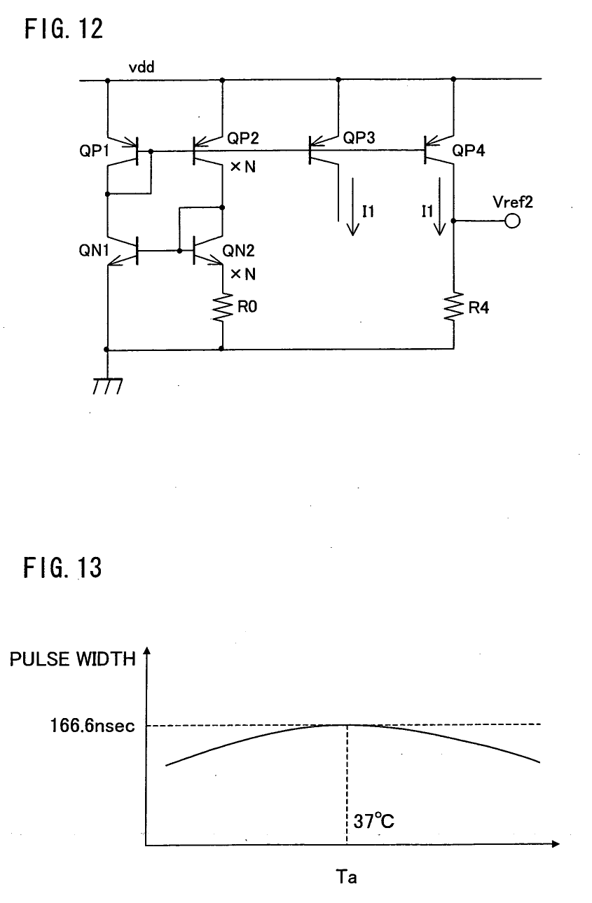

The following explains another embodiment of the present invention, with reference to FIGS. 12 to 14.

The present embodiment discloses a technique for making a pulse width constant at a point H shown in FIGS. 8 and 10, according to Embodiments 1 and 2.

The pulse width Tpw of an output voltage of the point H is expressed by formula (3). To make the pulse width Tpw constant, respective values of C3, Vref2, and I1 need to be constant. Exemplary factors of fluctuation in the values include fluctuation in temperature, and changes in processing.

Generally, it is easy to generate a PTAT (proportional to absolute temperature) current by use of a monolithic IC. Accordingly, it is possible to obtain a constant value of the current I1 that does not depend on temperature. FIG. 12 shows an exemplary PTAT current generating circuit.

The PTAT current generating circuit includes transistors QP1 to QP4, each of which is realized by a PNP-type bipolar transistor, transistors QN1 and QN2, each of which is realized by an NPN-type bipolar transistor, and resistors R0 and R4.

A base of the transistor QN1 and a base of the transistor QN2 are connected to each other. A connecting point of the bases of the transistors QN1 and QN2 is connected to a collector of the transistor QN2. An emitter of the transistor QN1 is connected to the GND. An emitter of the transistor QN2 is connected to one end of the resistor R0. The other end of the resistor R0 is connected to the GND. A ratio of size of between the transistor QN1 and the transistor QN2 is 1:N.

A base of the transistor QP1 and bases of the transistors QP2 to QP4 are connected to each other, and constitute a current mirror circuit. A connecting point of the bases is connected to a collector of the transistor QP1. The collector of the transistor QP1 is connected to a collector of the transistor QN1. An emitter of the transistor QP1 is connected to the power source vdd. A collector of the transistor QP2 is connected to a collector of the transistor QN2. An emitter of the transistor QP2 is connected to the power source vdd. The transistor QP2 causes a collector current to pass, which collector current is N-times greater than the collector current of the transistor QP1 to pass (ratio of size is 1:N).

An emitter of the transistor QP3 is connected to the power source vdd. A collector of the transistor QP3 is connected to a point C shown in FIGS. 8 and 10.

An emitter of the transistor QP4 is connected to the power source vdd. A collector of the transistor QP4 is connected to one end of the resistor R4. The other end of the resistor R4 is connected to the GND. Finally, the one end of the resistor R4 is connected, as a terminal for generating the reference voltage Vref2 shown in FIGS. 8 and 10, to a inverting input terminal of the comparator 35.

In the above configuration, the formula below is satisfied:
I1=Vt×(lnN)/R0 (4)
However,
Vt=k×T/q

(where k: Boltzmann's constant, T: absolute temperature, q: elementary charge of electron, N: ratio of size between (i) transistors QP1 and QN1 and (ii) transistors QP2 and QN2).

Further, a temperature coefficient is expressed by the formula below:
(∂I1/∂T)/I1=1/T−(∂R0/∂T)/R0

The current I1 also passes through the resistor R4. Therefore, if the reference voltage Vref2 is generated by using a voltage drop in the resistor R4, then the formula below is satisfied:

$$\begin{matrix}Vref 2 = R 4 \times I 1 \\ = R 4 \times Vt \times ( ln N ) / R 0\end{matrix} \qquad ( 5 )$$

At this time, the pulse width Tpw of the point H in the monostable multivibrator 20c is expressed by the formula below, on the basis of formulae (3) to (5):

$$\begin{matrix}Tpw = C 3 \times Vref 2 / I 1 \\ = C 3 \times R 4\end{matrix} \qquad ( 6 )$$

Accordingly, the pulse width Tpw is decided by the time constant C3×R4. Values of elements of the integrated circuit IC are affected by fluctuation in temperature and changes in processing.

The following explains the fluctuation in temperature. A current I1 is obtained that does not depend on temperature. Therefore, if respective values of the capacitor C3 and the resistor R4 do not fluctuate due to fluctuation in temperature, the pulse width Tpw does not fluctuate due to the fluctuation in temperature.

In general, a capacitance fluctuates less than a resistance does when the temperature fluctuates. Thus, it is possible to ignore the fluctuation in capacitance. At this time, the formulae below are satisfied, on the basis of formula (6):
∂Tpw/∂T=C3×∂R4/∂T
(∂Tpw/∂T)/Tpw=(∂R4/∂T)/R4
The temperature coefficient of the resistor R4 decides the fluctuation in the pulse width Tpw, which fluctuation is due to fluctuation in temperature.

To reduce fluctuation in resistor R4 due to fluctuation in temperature, there is a method in which the resistor R4 is configured with resistors each having a different temperature coefficient.

Generally, a diffusion resistance has a positive temperature coefficient (tc−rb). A resistance of polycrystalline silicon may have a negative temperature coefficient (tc−poly). At this time, if the resistor R4 is configured in accordance with the ratio below, it becomes possible to reduce the fluctuation due to the fluctuation in temperature:
(diffusion resistance):(resistance of polycrystalline silicon)={1/(tc−rb)}:{1/(tc−poly)} (7)
For example, suppose that the temperature coefficient tc−rb of the diffusion resistance is 500 ppm, and the temperature coefficient tc−poly of the resistance of polycrystalline silicon is −3000 ppm. If the ratio of formula (7) is set at 6:1, it becomes possible to sufficiently reduce the temperature coefficient of composite resistance.

This makes it possible to obtain a constant pulse width Tpw with respect to fluctuation in temperature. This allows the integrating circuit 20a to stably detect the direct-current component.

In this case, if there is provided a temperature compensating circuit that is configured with resistors each having a different temperature coefficient, it is difficult to obtain a constant resistance with respect to the resistor R4 for the entire temperature range (approximately −30° C. to 85° C.). The temperature coefficient of the resistance usually includes a second-order correction term. Thus, although the resistance is decided on the basis of the ratio of formula (7) using a temperature coefficient expressed solely with a first-order term, there exists a deviation of an amount that corresponds to the second-order correction term. FIG. 13 shows a pulse width-temperature characteristic of the temperature compensating circuit. The temperature is indicated as Ta in FIG. 13. There may be a case where the infrared receiver 1 is configured so as to be provided to an infrared wireless-earphone. An ordinary way of using the infrared receiver 1 is that it is placed on a human body. Therefore, if a characteristics curve of the temperature compensating circuit is realized such that the curve is flat at around human body temperature (approximately 37° C.), suitable characteristics are obtained under actual usage conditions. Accordingly, the characteristics curve is demanded to be flat in a temperature range including 37° C. The figure shows a curve as a consequence of fine adjustment of the ratio (diffusion resistance):(resistance of polycrystalline silicon) such that the pulse width Tpw takes a constant value of 166.6 nsec at around 37° C.

The following explains fluctuation in the respective values of the capacitor C3 and the resistor R4, which fluctuation is due to changes in processing. As it is apparent from formula (6), the pulse width Tpw is affected by the fluctuation in the respective values of the capacitor C3 and the resistor R4, which fluctuation is due to changes in processing. Generally, in an integrated circuit, a capacitance fluctuates approximately between ±10%, and a resistance fluctuates approximately between ±20%. The pulse width Tpw is expressed by the time constant C3×R4. Therefore, it is possible to make the pulse width Tpw constant by making the time constant invariable. Thus, only the resistance of the resistor is adjusted by the trimming circuit, and the time constant C3×R4 is adjusted. By this way, it becomes possible to reduce influence of the changes in processing.

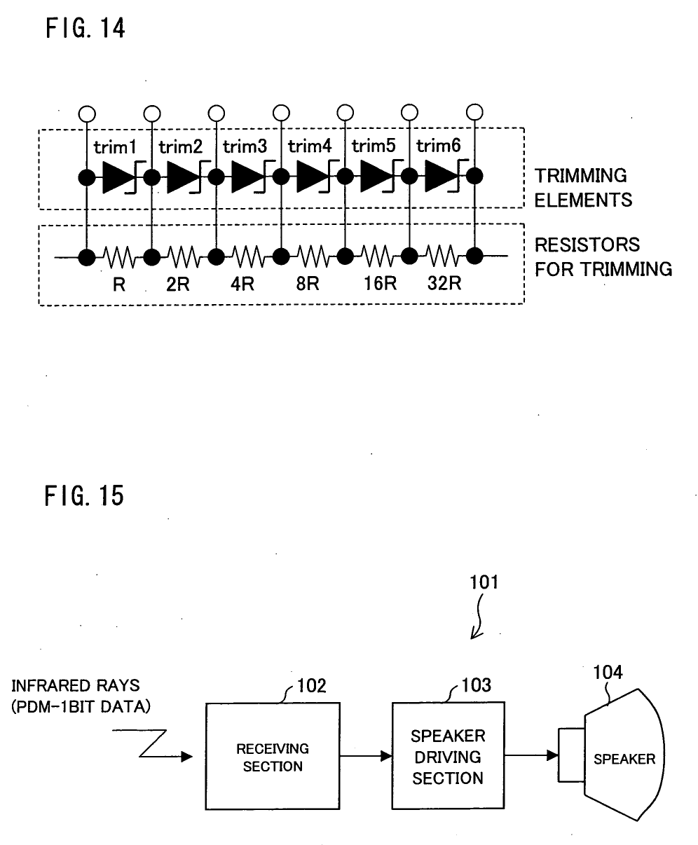

FIG. 14 shows an exemplary trimming circuit.

Resistors 2ⁿR (n indicates a trimming bit number, and is a whole number that is 0 or greater), which are resistors R, 2R, 4R . . . , are sequentially connected in serial, and trimming element trims 1, 2 . . . are connected in parallel to the respective resistors. The trimming elements cause the resistances that are connected in parallel to the trimming elements, respectively, to short. Thus, a trimming element is opened that is connected in parallel to a selected resistance, among the resistors 2ⁿR. For example, if the resistors 2R, 8R, and 32R are selected to obtain a composite resistance 42R of the resistors 2R, 8R, and 32R, then the trimming element trims 2, 8, and 32 are opened. Known trimming methods that can be performed in an IC include: polycrystalline silicon laser trimming; polycrystalline silicon fusion trimming; and zener-zap diode trimming.

The present invention is not limited to the description of the embodiments above, but may be altered by a skilled person within the scope of the claims. An embodiment based on a proper combination of technical means disclosed in different embodiments is encompassed in the technical scope of the present invention.

What is claimed is:

1. A receiver that receives audio data via wireless, which audio data, constituted of 1-bit data sequence which has been subjected to pulse density modulation, is transmitted via baseband transmission,
the receiver comprising:
detecting means for detecting a bit error rate; and
comparing means for (I) comparing the bit error rate detected by the detecting means with a predetermined reference rate, and (II) outputting, (a) when the bit error rate is smaller than the reference rate, a signal that causes an output of reproduction of the audio data thus received to become ON, and, (b) when the bit error rate is greater than the reference rate, a signal that causes the output to become OFF.

2. The receiver according to claim 1, wherein:
the detecting means includes an integrator to detect a direct-current component of a received signal; and
the comparing means includes a comparator to compare the direct-current component detected by the integrator with a reference voltage that is determined in accordance with the reference rate.

3. A receiver according to claim 1, further comprising:
a monostable multivibrator circuit to generate and output a new pulse in response to each received pulse that constitutes the 1-bit data sequence of the audio data thus received,
the detecting means (I) being supplied with the new pulse that is outputted by the monostable multivibrator circuit and (II) including an integrator to detect a direct-current component of the new pulse, and
the comparing means including a comparator to compare the direct-current component detected by the integrator with a reference voltage that is determined in accordance with the reference rate.

4. A receiver according to claim 1, further comprising:
bit-error correcting means for carrying out, before the detecting means detects the bit error rate, a bit error correction by eliminating a bit error that is caused by a split-pulse.

5. A receiver according to claim 4, further comprising:
a monostable multivibrator circuit to generate and output a new pulse in response to each received pulse that constitutes the 1-bit data sequence of the audio data thus received,
the bit-error correcting means causing the monostable multivibrator circuit to correct the split-pulse so that the split-pulse becomes a normal pulse when the monostable multivibrator circuit generates the new pulse,
the detecting means (I) being supplied with the new pulse that is outputted by the monostable multivibrator circuit and (II) including an integrator to detect a direct-current component of the new pulse, and
the comparing means including a comparator to compare the direct-current component detected by the integrator with a reference voltage that is determined in accordance with the reference rate.

6. The receiver according to claim 2, wherein the integrator has a cut-off frequency that is equal to or below a voice band.

7. The receiver according to claim 3, wherein the integrator has a cut-off frequency that is equal to or below a voice band.

8. The receiver according to claim 5, wherein the integrator has a cut-off frequency that is equal to or below a voice band.

9. The receiver according to claim 2, wherein the comparator has a hysteresis characteristic.

10. The receiver according to claim 3, wherein the comparator has a hysteresis characteristic.

11. The receiver according to claim 5, wherein the comparator has a hysteresis characteristic.

12. A receiver according to claim 3, further comprising:
a temperature compensating circuit to perform a temperature compensation for a pulse-width of the new pulse that is outputted by the monostable multivibrator circuit.

13. A receiver according to claim 5, further comprising:
a temperature compensating circuit to perform a temperature compensation for a pulse-width of the new pulse that is outputted by the monostable multivibrator circuit.

14. The receiver according to claim 12, wherein the temperature compensating circuit has a pulse-width-temperature characteristic that causes the pulse-width to be constant at around 37° C.

15. The receiver according to claim 13, wherein the temperature compensating circuit has a pulse-width-temperature characteristic that causes the pulse-width to be constant at around 37° C.

16. The receiver according to claim 12, wherein the temperature compensating circuit has a trimming circuit to adjust a pulse-width-temperature characteristic.

17. The receiver according to claim 13, wherein the temperature compensating circuit has a trimming circuit to adjust a pulse-width-temperature characteristic.

18. An infrared wireless-earphone comprising a receiver defined in claim 1,
the baseband transmission being performed via infrared rays, and
the receiver outputting sound via an earphone.
